(19) United States
(12) Patent Application Publication
(10) Pub. No.: US 2019/0279925 A1
(43) Pub. Date: Sep. 12, 2019

(54) SEMICONDUCTOR PACKAGE STRUCTURE AND METHOD OF MAKING THE SAME

(71) Applicant: Phoenix Pioneer Technology Co., Ltd., Hsinchu County (TW)

(72) Inventors: Shih-Ping Hsu, Hsinchu County (TW); Chun-Hsien Yu, Hsinchu County (TW); Hsien-Ming Tsai, Hsinchu County (TW)

(21) Appl. No.: 16/291,065

(22) Filed: Mar. 4, 2019

(30) Foreign Application Priority Data
Mar. 8, 2018 (TW) 107107834

(51) Int. Cl. H01L 23/498; H05K 3/34; H01L 23/00; H01L 23/522; H01L 21/82

(52) U.S. Cl. CPC H01L 23/49816; H05K 3/3436; H01L 24/17; H01L 23/5226; H01L 2225/06513; H01L 24/81; H01L 21/82; H01L 2924/14; H05K 2201/10734; H01L 24/97

(57) ABSTRACT

A semiconductor package structure includes a chip and a substrate having a recess. The substrate includes a base dielectric layer as the bottom of the recess, and numbers of supporting dielectric layers as the side surfaces of the recess. The substrate further includes a base connecting layer in the base dielectric layer, and numbers of supporting connecting layers in the supporting dielectric layers. Portions of the base connecting layer exposed on the bottom of the recess are first connection pads, and portions of the base connecting layer exposed on the bottom of the base dielectric layer are bottom connection pads. The active surface of the chip is turned toward the base dielectric layer, and the chip is located on the bottom of the recess. The active surface of the chip is electrically connected to the first connection pads. Since the chip is embedded in the recess, and is electrically connected to the first connection pads, the invention provides a thinner system package and increases the structural reliability.

### CROSS REFERENCE TO RELATED APPLICATIONS

This Non-provisional application claims priority under 35 U.S.C. § 119(a) on Patent Application No. 107107834 filed in Republic of China on Mar. 8, 2018, the entire contents of which are hereby incorporated by reference.

### BACKGROUND

### 1. Technical Field

This invention relates to a substrate for flip chip packages, in particular, to a thin multi-chip package and a manufacturing method thereof.

### 2. Description of Related Art

Semiconductor package provides protection against impact and corrosion, holds the contact pins or leads which are used to connect from external circuits to the device, and dissipates heat produced in the device. Packaging of an electronic system must consider protection from mechanical damage, cooling, radio frequency noise emission, protection from electrostatic discharge, maintenance, operator convenience, and cost. The substrates serve as the connection between integrated circuit (IC) chips and the printed circuit board (PCB) through a conductive network of traces and holes. The substrates support critical functions including circuit support and protection, heat dissipation, and signal and power distribution.

With the continued development of electronics industries, there has been rapidly increasing consumer demand for devices that are multi-functional, more convenient, and smaller. This demand has driven the need for increased IC density. Increased input-output (I/O) pin count and increased demands for IC density have led to the development of chip packages. Wire bonding (WB) and flip-chip assembly are the principal methods for interconnecting ICs. Wire bonding is a method in which wires are used to interconnect the electric pads of the chip to external circuitry of the substrate. Flip chip is a method for interconnecting the electric pads of the chip to external circuitry of the substrate with solder bumps that have been deposited onto the chip pads.

There is another package structure that uses both wire bonding and flip-chip technology in one package. The substrate for flip-chip technology is thick due to the interconnections of the flip-chip substrate, and the molding layer for wire bonding technology is thick due to the bonding wires. Thus, the package that uses both wire bonding and flip-chip technology is inconvenient for smaller or thinner devices, such as portable devices. In addition, such package has a poor heat-dissipation due to the thickness and poor heat transfer coefficient of the substrate material. Furthermore, the number of the input/output connection pads is limited in such package, because the solder mask and bumps for flip-chip technology lead to a large pitch of the input/output connection pads.

Many different packaging techniques have been developed for stacking many standard chip dies into a compact area. A system in package (SiP) or system-in-a-package is primarily being driven by market trends in wearable and mobile devices. This is particularly valuable in space-constrained environments like portable devices and mobile phones as it reduces the complexity of the printed circuit board and overall thickness. Package on package (PoP) is one of the SiP methods to combine vertically discrete logic and memory ball grid array (BGA) packages with big bumps. Two or more packages are installed atop each other with a standard interface to route signals between them.

FIG. 1 is a schematic diagram illustrating a prior art PoP structure 900. As shown in FIG. 1, the PoP structure 900 includes a first substrate 934, numbers of interconnection layers 913, a first encapsulating material layer 915 located on the first substrate 934, a first chip 910 embedded in the first encapsulating material layer 915, a second substrate 935 stacked on the first encapsulating material layer 915, a second chip 920 located on the second substrate 935, a third chip 930 located on the second chip 920, and a second encapsulating material layer 925 located on the second substrate 935. The interconnection layers 913 are formed in the first substrate 934 and the second substrate 935, and include redistribution layers (RDL) and via plugs. It is noticed that the second substrate 935 is electrically connected to the first substrate 934 through big solder balls 926.

Despite its benefits, the solder balls 926 with a thickness larger than the chip thickness of the first chip 910 are necessary to connect the second substrate 935 and the first substrate 934 in the PoP structure 900. A thickness (height) of the solder balls 926 is about 250 micrometers (μm), so the pitches between two solder balls 926 are about 500˜600 micrometers. The big solder balls 926 and the large pitches between solder balls 926 lead to huge area of the first substrate 934 and the second substrate 935, and therefore an interlayer compensation liner must be additionally formed as pads for the solder balls 926.

The huge area and dis-match in coefficient of thermal expansion (CTE dis-match) of the first substrate 934 and the second substrate 935 cause internal stress in the PoP structure 900, and the internal stress leads to warpage problem of the substrates 934 and 935. The warpage causes poor contact amount the solder balls 926 and the substrates 934 and 935. Moreover, the high-low temperature cycle test and the high temperature rewinding cooling test also lead to breakage of the solder joints or rupture of the solder balls 926. As a result, the reliability of the package structure is reduced. Another disadvantage is that, since two substrates (the first substrate 934 and the second substrate 935) with interconnection layers 913 are needed to input/output the signals of the first chip 910 and the second chip 920, and the second molding layer 925 is thick due to the bonding wires, the overall thickness of the PoP structure 900 is still large.

An integrated fan-out (InFO) wafer level system integration (WLSI) technology has been developed to stacked application processor chip and memory package for smart mobile devices through thick copper plugs. The process involves dicing the chips on a silicon wafer, and then very precisely stacking the chips on a thin reconstituted or carrier wafer, which is then molded. The thick copper plugs are created around the lower chip, and then solder bumps are formed to connect the package to the printed wiring board directly. Compared to the chip thickness of the lower chip, large numbers of copper plating processes are needed to form the copper plugs with a bigger thickness to support the upper chip. Although the fan-out wafer level packaging may be a solution for some designs, it is not always the lowest cost solution. There is more performance with the thick copper plugs in the wafer level package than the normal connections in the traditional package. The technical threshold of the wafer level package is higher and more expensive than the traditional package technology, so the fan-out wafer level packaging is not universal.

### SUMMARY OF THE INVENTION

It is therefore an object of the present invention to provide a semiconductor package structure and the making method, which have support connection layers around the lower chip to support the upper chip and to redistribute the traces. Accordingly, the overall thickness of the package is decreased and the production reliability is improved.

To achieve the above, the present invention is to provide a semiconductor package structure including a first chip and a substrate. The first chip has a first active surface and a first back surface opposite to the first active surface. The substrate includes a basic dielectric layer, a basic connection layer, numbers of support dielectric layers and numbers of support connection layers. The basic dielectric layer has a basic top surface and a basic bottom surface opposite to the basic top surface. The basic connection layer is located in the basic dielectric layer. The basic connection layer includes numbers of first connection pads exposed on the basic top surface and numbers of bottom connection pads exposed on the basic bottom surface. Both the support dielectric layers and the first chip are located on the basic top surface. The support dielectric layers and the basic dielectric layer together shape a chip-placing recess. The first chip is located in the chip-placing recess with the first active surface downward to the basic dielectric layer. The first active surface of the first chip is electrically connected to the first connection pads. The support connection layers are located in the support dielectric layers. The support connection layers include numbers of second connection pads exposed on the support top surface.

In one embodiment of the present invention, the semiconductor package structure further includes a second chip. The second chip has a second active surface and a second back surface opposite to the second active surface. The second chip is located above the first chip and the support top surface of the support dielectric layers, and the second chip is electrically connected to the second connection pads through the second active surface downwardly.

To achieve the above, the present invention is to provide a method of manufacturing a semiconductor package structure. First, a carrier is provided. Subsequently, a basic connection layer and a basic dielectric layer are formed on the carrier. The basic connection layer is located in the basic dielectric layer. A basic top surface of the basic dielectric layer has a chip-placing area. Next, a release film is provided on the chip-placing area. Thereafter, numbers of support dielectric layers and numbers of support connection layers are formed on the basic dielectric layer. The support dielectric layers are located on the basic top surface of the basic dielectric layer. The support connection layers are located in the support dielectric layers. The support connection layers include numbers of second connection pads exposed on the support top surface of the support dielectric layers. Next, a dicing process is performed on the chip-placing area to remove parts of the support dielectric layers and parts of the release film located on the chip-placing area and to expose the chip-placing area. The support dielectric layers and the basic dielectric layer together shape a chip-placing recess. Thereafter, the carrier is removed. The basic connection layer includes numbers of first connection pads exposed on the basic top surface of the basic dielectric layer, and numbers of bottom connection pads exposed on a basic bottom surface of the basic dielectric layer.

In one embodiment, since the binding force between the support dielectric layer with the release film is greater than the binding force between the chip-placing area with the release film so that the release film is separated from the chip-placing area by internal stress when performing the laser dicing process.

In one embodiment of the present invention, the present invention further includes a step of providing a protective film covering the support top surface of the support dielectric layers, before the dicing process is performed. The protective film protects the second connection pads during the dicing process. Afterward, an etching process is performed on the basic connection layer in the chip-placing area to expose the first connection pads, and next the protective film is removed.

Accordingly, the present invention relates to a substrate, which utilizes the build-up interconnection technology and rear recess forming technology to form first connection pads on the recess bottom for a flip chip package. The lower chip is partially or wholly embedded in the recess, and is electrically connected to the first connection pads on the recess bottom. One or more chips may be stacked on the lower chip. Thus, the present invention provides a thinner system package and increases the structural reliability.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

The parts in the drawings are not necessarily drawn to scale, the emphasis instead being placed upon clearly illustrating the principles of at least one embodiment. In the drawings, like reference numerals designate corresponding parts throughout the various diagrams, and all the diagrams are schematic.

FIG. 1 is a schematic diagram illustrating a prior art package on package (PoP) structure.

FIG. 2 is a schematic diagram illustrating a semiconductor package structure according to the first embodiment of the present invention.

FIG. 3 is a top view of the semiconductor package structure according to the first embodiment of the present invention.

FIG. 4 is a bottom view of the semiconductor package structure according to the first embodiment of the present invention.

FIG. 5 is a schematic diagram illustrating a semiconductor package structure according to a second embodiment of the present invention.

FIG. 6 is a schematic diagram illustrating a semiconductor package structure according to a third embodiment of the present invention.

FIG. 7 through FIG. 18 are schematic diagrams illustrating a method of making a semiconductor package structure according to the present invention.

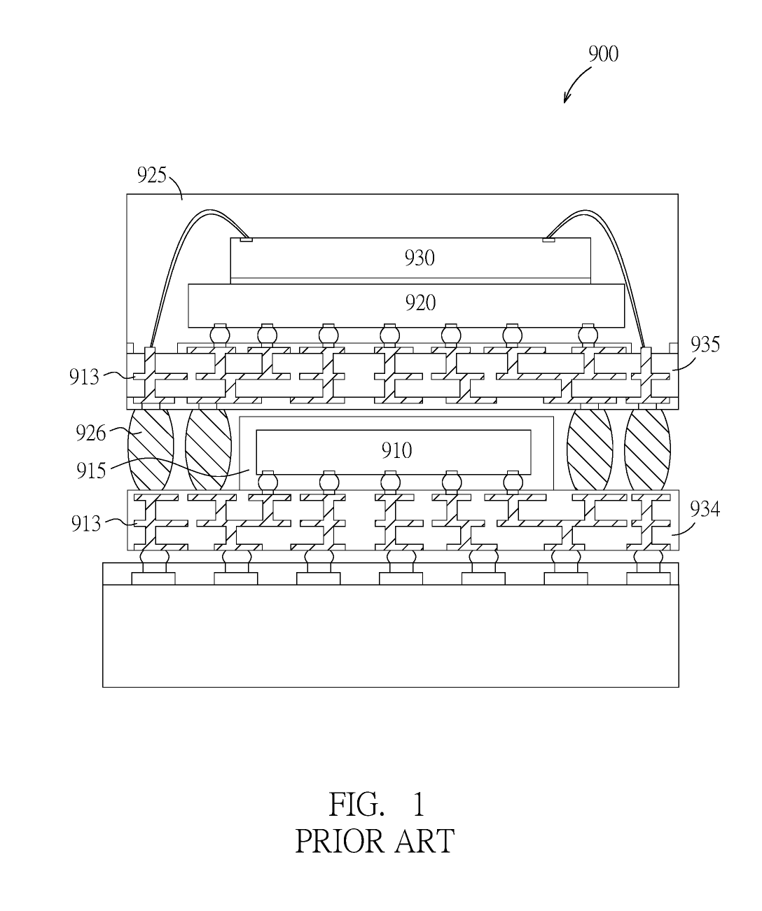

### DETAILED DESCRIPTION

Reference will now be made to the drawings to describe various inventive embodiments of the present disclosure in detail, wherein like numerals refer to like elements throughout.

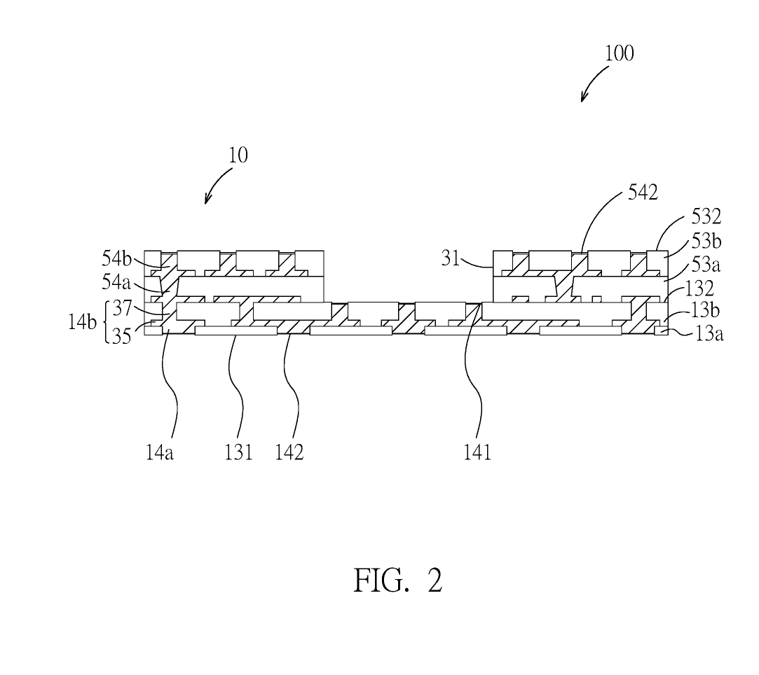

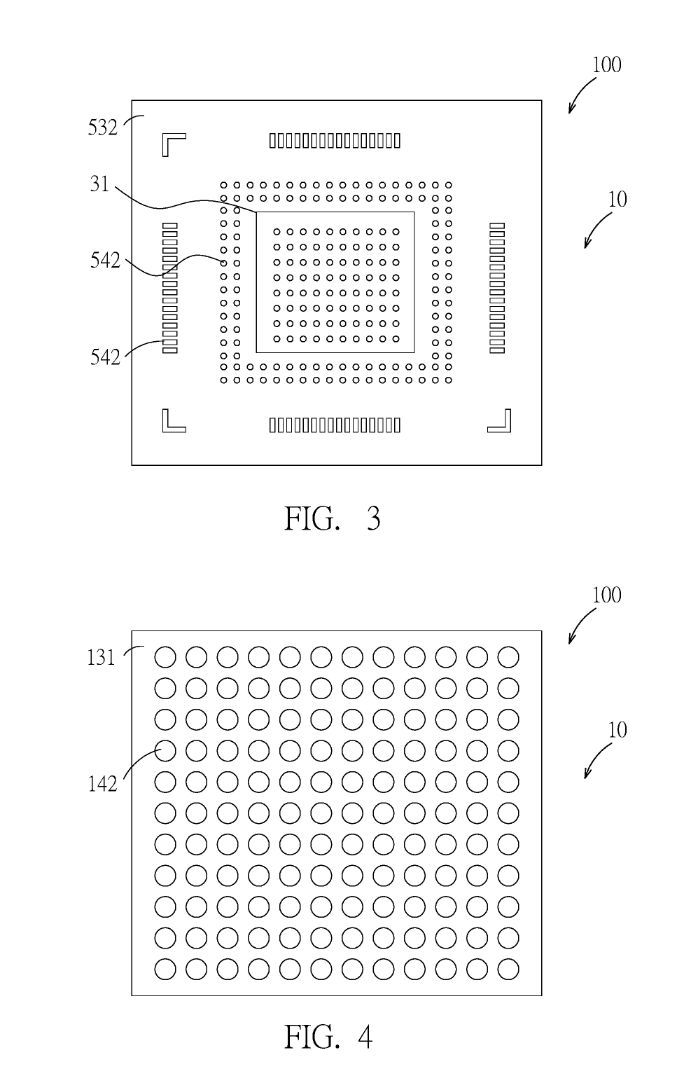

FIG. 2 through FIG. 4 are a schematic diagram, a top view and a bottom view of a semiconductor package structure 100 according to the first embodiment of the present invention. As shown in FIG. 2 through FIG. 4, the semiconductor package structure 100 of this embodiment includes a substrate 10, which has a chip-placing recess 31 for a flip chip package. The substrate 10 includes two basic dielectric layers 13a, 13b and two support dielectric layers 53a, 53b from the bottom to the top. The support dielectric layers 53a, 53b and the basic dielectric layers 13a, 13b together shape the chip-placing recess 31. Specifically speaking, the basic dielectric layers 13a, 13b are stacked on the bottom as the bottom of the chip-placing recess 31, and the support dielectric layers 53a, 53b are stacked on the basic dielectric layer 13b as the sidewalls of the chip-placing recess 31. The stacked basic dielectric layers 13a, 13b have a basic top surface 132 and a basic bottom surface 131 opposite to the basic top surface 132. The support dielectric layers 53a, 53b have a support top surface 532. In other words, the support dielectric layers 53a, 53b are located on the basic top surface 132 of the basic dielectric layers 13a, 13b.

In the embodiment, the basic dielectric layers 13a, 13b and the support dielectric layers 53a, 53b may be one of the high filler content dielectric material, which is based on epoxy resin as the main material. In epoxy molding compound, the epoxy resin is about 8 wt. % to 12 wt. % and the filler is about 70 wt. % to 90 wt. %. The filler may include silica and alumina to increase the mechanical strength, reduce the linear thermal expansion coefficient, increase heat conduction, increase water resistance and reduce the effectiveness of rubber overflow. The number of the basic dielectric layers 13a, 13b is not limited by this embodiment. The basic dielectric layers 13a, 13b may be one or more layers laminate structure in other embodiment.

The substrate 10 further includes two basic connection layers 14a, 14b and two support connection layers 54a, 54b. The basic connection layers 14a, 14b are located in the basic dielectric layers 13a, 13b individually. The support connection layers 54a, 54b are located in the support dielectric layers 53a, 53b individually. The stacked basic connection layers 14a, 14b include numbers of bottom connection pads 142, a redistribution layer 35 and numbers of via plugs 37 from bottom to top. Individually speaking, the lower basic connection layer 14a includes the bottom connection pads 142 in the lower basic dielectric layer 13a, and the upper basic connection layer 14b includes the redistribution layer 35 and the via plugs 37 in the upper basic dielectric layer 13b. Portions of the via plugs 37 exposed on the bottom of the chip-placing recess 31 (the basic top surface 132) are applied as the first connection pads 141. Portions of the bottom connection pads 142 are exposed on the basic bottom surface 131.

Each of the support connection layers 54a, 54b includes a redistribution layer 35 and a layer of via plugs 37 on the redistribution layer 35. Portions of the via plugs 37 exposed on the support top surface 532 are applied as the second connection pads 542. In other words, the two support connection layers 54a, 54b include a redistribution layer 35, a layer of via plugs 37 on the said redistribution layer 35, another redistribution layer 35 on the said layer of via plugs 37, another layer of via plugs 37 on the upper redistribution layer 35, and the second connection pads 542 from bottom to top. The redistribution layer 35 in the lower support connection layers 54a is electrically connected to the via plugs 37 in the basic connection layer 14b.

The via plugs 37 are applied to electrically connect the redistribution layers 35 to each other. The redistribution layers 35 may redistribute the interconnecting traces to adjust the positions of the input/output connection pads. Accordingly, the redistribution layers 35 conect the chips, extend outwardly from the chips, and function as a fan out structure. Since the redistribution layers 35 redistribute the positions of the connection pads, a projection of the support connection layers 54a, 54b projected on the support top surface 532 is different from a projection of the second connection pads 542 projected on the support top surface 532. In other words, the pattern of the support connection layers 54a, 54b is different from the pattern of the second connection pads 542 in the top view. The redistribution layers 35 and the via plugs 37 may include cupper metal.

The first connection pads 141 are the connection pads for the chip located in the chip-placing recess 31 to flip on. The second connection pads 542 located on the support top surface 532 are the connection pads for other chips to connect through bumps or wires. The bottom connection pads 142 on the basic bottom surface 131 are the connection pads for electrically connecting to a printed circuit board (PCB). The exposed surfaces of the first connection pads 141, the second connection pads 542 and the bottom connection pads 142 may be flush with or higher than the surfaces of the dielectric layers around the pads according to the chip design or molding requirement. The first connection pads 141, the second connection pads 542 and the bottom connection pads 142 flush with the nearby dielectric layers are easier for the copper plugs connecting process, while those connection pads higher than the nearby dielectric layers are easier for the solder balls connecting process.

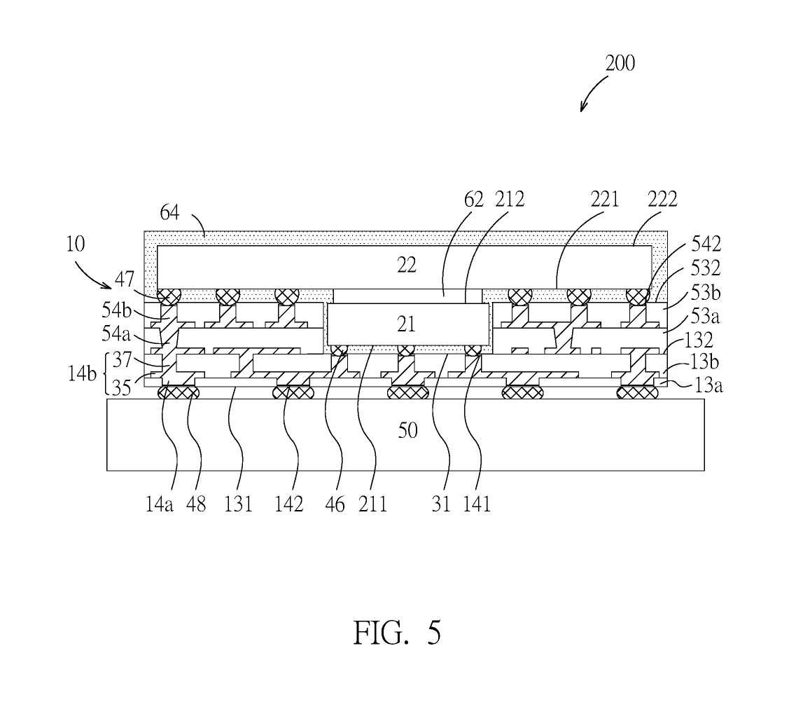

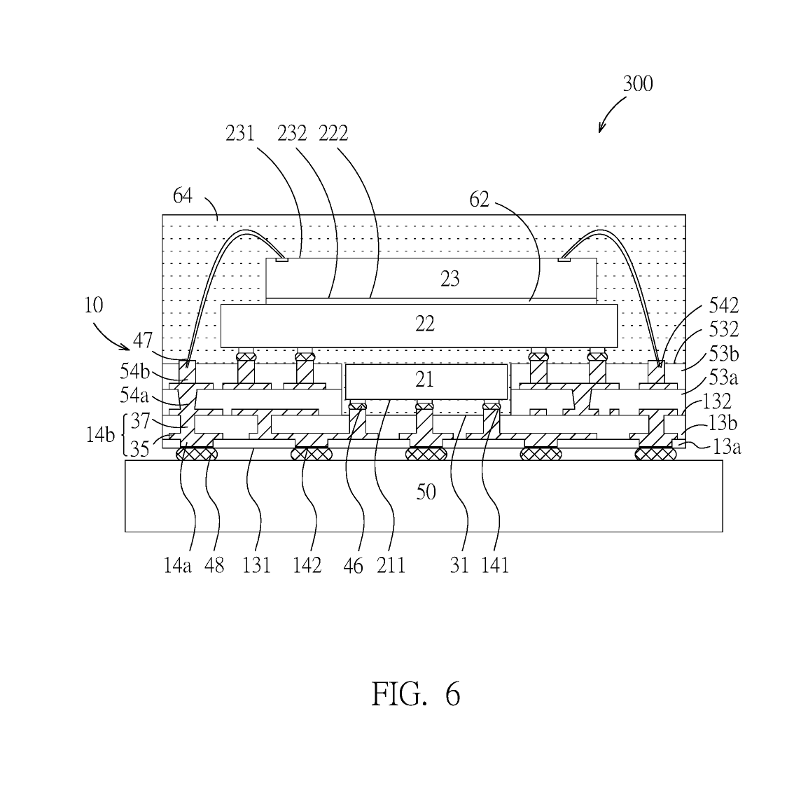

The package structures of the present invention after performing die bond processes, molding processes and PCB processes on the substrate 10 are shown in FIG. 5 and FIG. 6. FIG. 5 and FIG. 6 are schematic diagrams illustrating two semiconductor package structures 200, 300 according to the second and the third embodiments of the present invention. The main differences from the first embodiment are that, the semiconductor package structure 200 of the second embodiment includes two chips 21, 22, and the semiconductor package structure 300 of the third embodiment includes three chips 21, 22, 23.

As shown in FIG. 5, the semiconductor package structure 200 includes a substrate 10, a first chip 21, a second chip 22, a buffer layer 62, numbers of first bumps 46, numbers of second bumps 47 and an encapsulation layer 64. The first chip 21 has a first active surface 211 and a first back surface 212 opposite to the first active surface 211. The whole first chip 21 is embedded in the chip-placing recess 31 of the substrate 10 with the first active surface 211 downward to the basic dielectric layers 13a, 13b. The first chip 21 is located on the basic top surface 132 of the basic dielectric layers 13a, 13b. The first bumps 46 electrically connect the first active surface 211 of the first chip 21 and the first connection pads 141 to form the flip chip connection.

The second chip 22 has a second active surface 221 and a second back surface 222 opposite to the second active surface 221. The second chip 22 is located above the first chip 21 and the support top surface 532 of the support dielectric layers 53b. The second chip 22 is located above the first chip 21 and the buffer layer 62, with its second active surface 221 downwardly. The second bumps 47 electrically connect the second active surface 221 of the second chip 22 and the second connection pads 542 to form the flip chip connection. The first chip 21 and the second chip 22 may be any kinds of chips, dies, active components or inactive components, such as the power management integrated circuit (PMIC), the high bandwidth memory (HBM), the integrated circuit chip or the light emitting diode (LED) chip.

The buffer layer 62 is located between the first chip 21 and the second chip 22 to protect the first chip 21 and the second chip 22. The buffer layer 62 may include any elastic materials, such as silicone film or adhesive glue, and is not limited thereto. The encapsulation layer 64 covers the substrate 10, the first chip 21, the second chip 22, the buffer layer 62, the first bumps 46 and the second bumps 47. The encapsulation layer 64 may be one of the high filler content dielectric material, which is based on epoxy resin as the main material to increase the mechanical strength, reduce the linear thermal expansion coefficient, increase heat conduction, increase water resistance and reduce the effectiveness of rubber overflow.

The semiconductor package structure 200 further includes a PCB 50 and numbers of third bumps 48 optionally. The third bumps 48 are located on the basic bottom surface 131 of the substrate 10, and function as the outer connection pads. In other words, the third bumps 48 electrically connect the semiconductor package structure 200 to the PCB 50.

In this embodiment, the first back surface 212 of the first chip 21 is substantially even with the support top surface 532 of the support connection layers 54a, 54b, but is not limited thereto. In detail, the first back surface 212 of the first chip 21 may be a little higher than the support top surface 532 of the support dielectric layers 53b, and a preferred distance between the first back surface 212 and the support top surface 532 is less than a diameter of solder balls. The first back surface 212 of the first chip 21 may be lower than the support top surface 532 of the support dielectric layers 53b in other embodiment. In case that there is a bigger distance between the first chip 21 and the second chip 22, the buffer layer 62 may be omitted in the present invention, and the encapsulation layer 64 may fill the gap between the first chip 21 and the second chip 22 as a buffer.

The main differences from the second embodiment is that, the semiconductor package structure 300 of the third embodiment further includes a third chip 23, as shown in FIG. 6. The third chip 23 has a third active surface 231 and a third back surface 232 opposite to the third active surface 231. The third chip 23 is located on the second chip 22 with the third active surface 231 upwardly, and the third chip 23 is electrically connected to the second connection pads 542 through numbers of wires.

According to the structure of the substrate 10 for the flip chip package, the lower first chip 21 is partially or wholly embedded in the chip-placing recess 31 of the substrate 10, and the second and the third chips 22, 23 are stacked above the lower first chip 21. Thus, the embedded structure can provide a thinner system package as a whole. In addition, since the single substrate 10 of the present invention can provide both support and interconnection for numbers of chips 21, 22, 23, no more huge copper plugs or giant solder balls (plugs or solder balls with diameters bigger than or near to the thickness of the chip) are needed. As a result, interlayer compensation liners are omitted, and the pitches between two pads are reduced.

Furthermore, the embedded first chip 21 of the present invention is closer to the basic bottom surface 131 of the substrate 10 than the traditional chip, so the trace length of the interconnections can be reduced, and the heat dissipation is improved. Accordingly, the poor heat-dissipation problem of the traditional system package is solved.

Moreover, since the dielectric layers of the substrate 10 include the high filler content dielectric material, in replace of the welding resin in the traditional PCB, the substrate 10 increase the mechanical strength, material combinations, heat conduction and product reliability in the present invention.

Additionally, since the substrate 10 of the present invention is formed by the copper connection in molding (C2iM) build-up technology, traces and interconnections can be freely arranged in the sidewalls of the chip-placing recess 31 and in portions of the substrate 10 under the chip-placing area. The number and thicknesses of the interconnection layers can be adjusted as required. Thus, design of traces and interconnections is more flexible and the overall size of the package can be reduced.

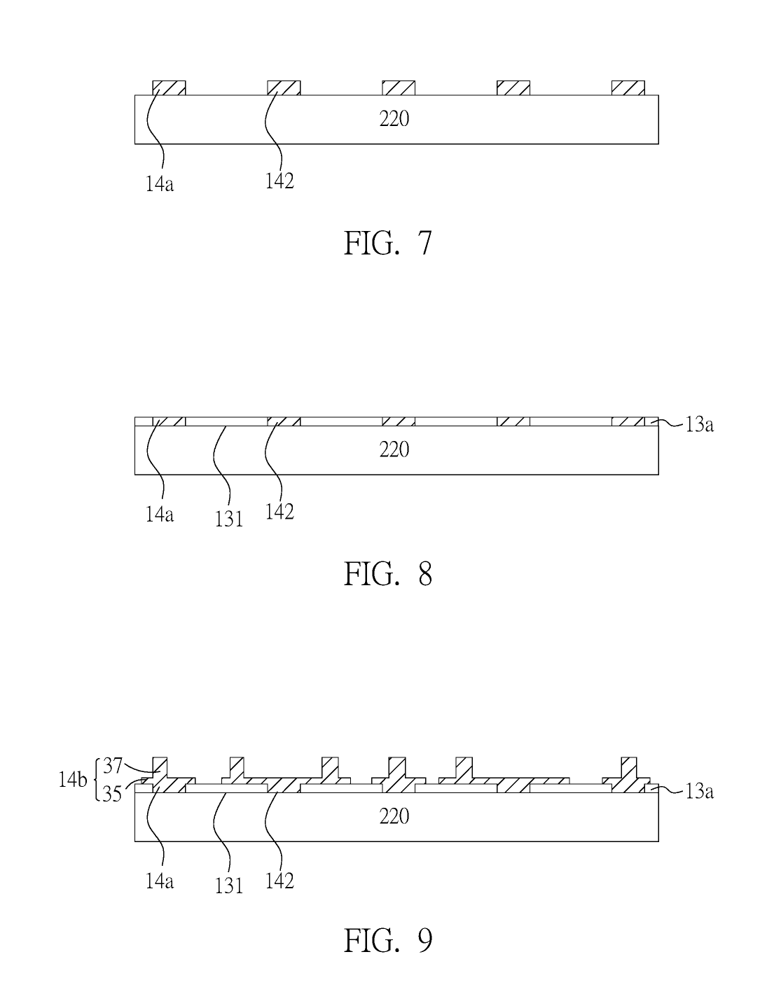

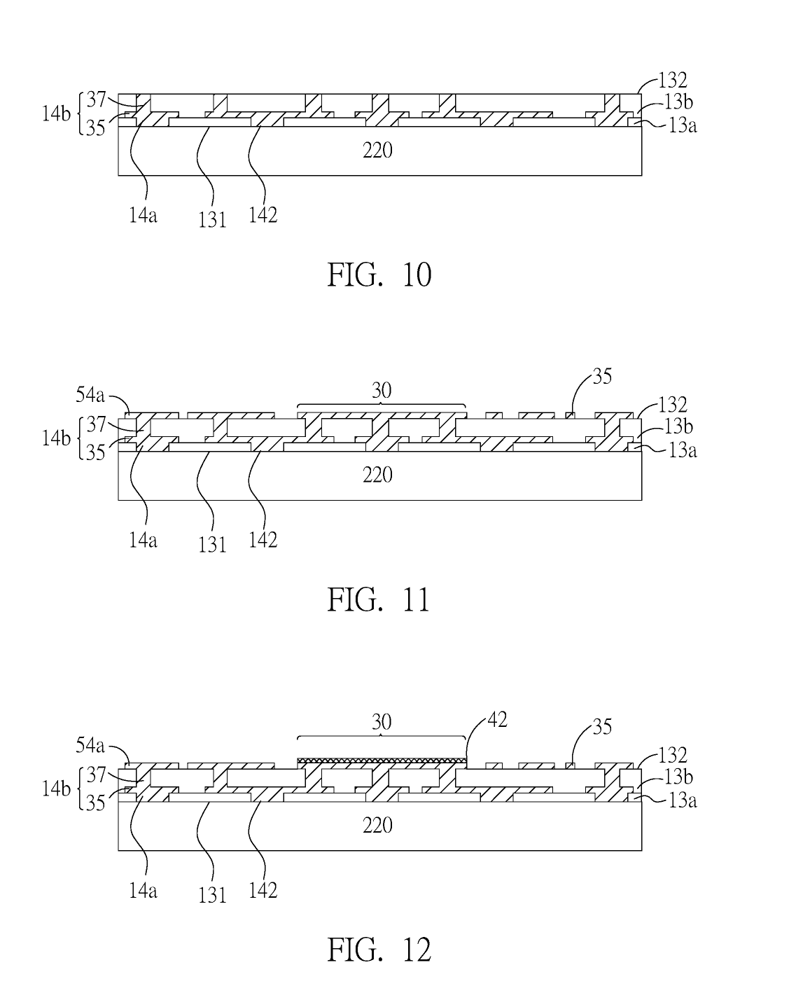

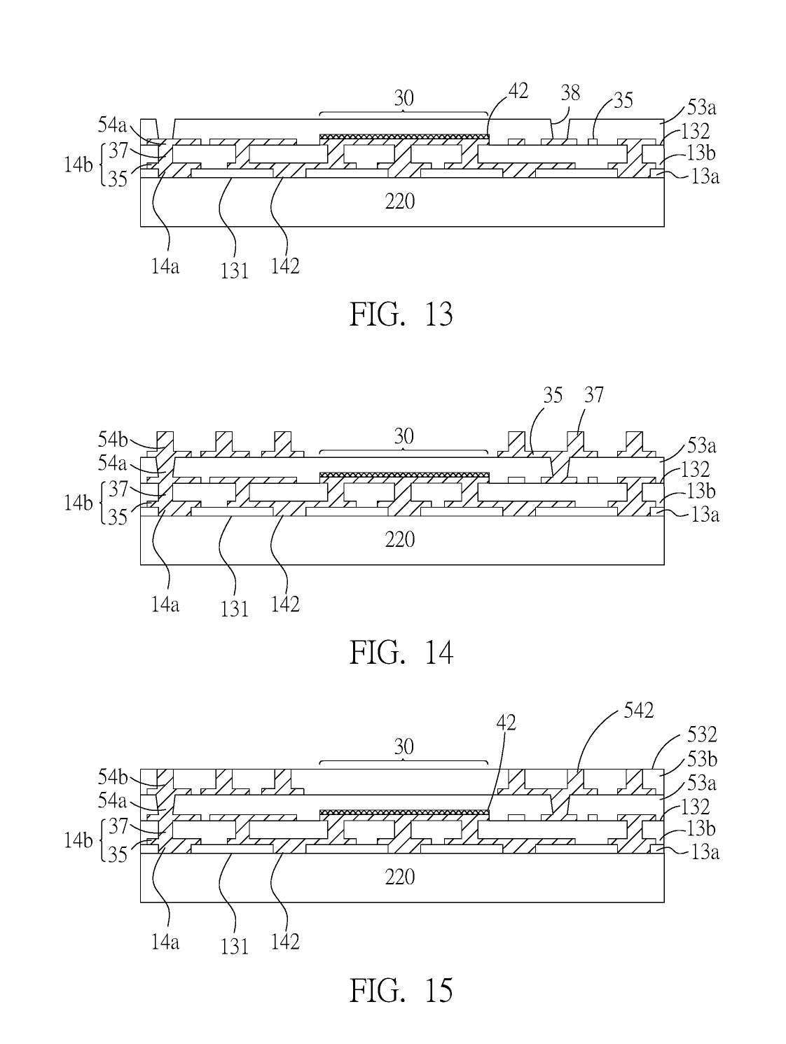

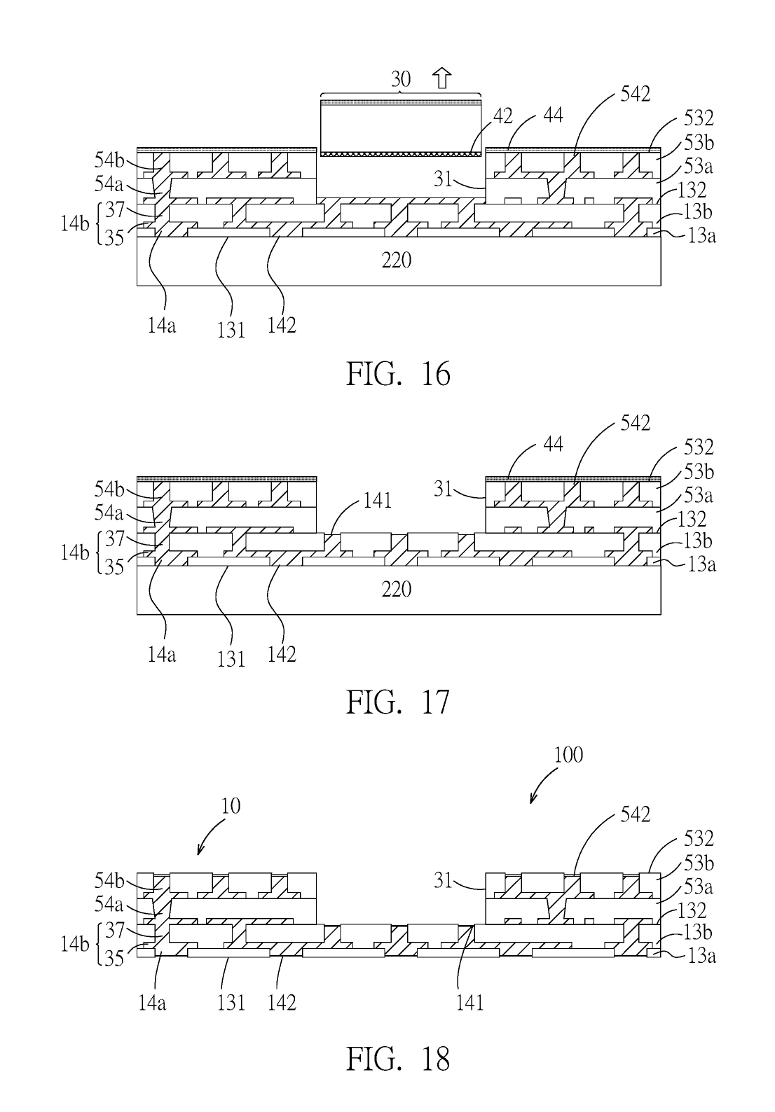

FIG. 7 through FIG. 18 are schematic diagrams illustrating a method of making a semiconductor package structure 100 according to the present invention. A brief introduction of the method of making the semiconductor package structure 100 substantially includes forming the bottom connection pads 142 on the carrier 220 (FIG. 7), performing molding and grinding processes to form the lower basic dielectric layer 13a (FIG. 8), forming the upper basic connection layer 14b with a semi-additive process (SAP) (FIG. 9), performing molding and grinding processes to form the upper basic dielectric layer 13b (FIG. 10), forming the redistribution layer 35 of the lower support connection layers 54a with a semi-additive process (FIG. 11), adhering the release film 42 (FIG. 12), performing molding and drilling processes to form the lower support dielectric layers 53a (FIG. 13), forming the via plugs 37 and the upper support connection layers 54b (FIG. 14), performing molding and grinding processes to form the upper support dielectric layers 53b (FIG. 15), providing the protective film 44 and performing a dicing process to form the recess (FIG. 16), performing an etching process to expose the first connection pads 141 (FIG. 17), and removing the carrier 220 (FIG. 18). The method of making the semiconductor package structure 100 is further described as following.

First, as shown in FIG. 7, a carrier 220 is provided. Substantially, numbers of bottom connection pads 142, which are also the basic connection layer 14a, are formed on the carrier 220 through performing a copper plating process. For example, the method of forming the bottom connection pads 142 includes forming a copper layer on the carrier 220, covering the copper layer with a plating resist, patterning the plating resist through exposure and development processes to form a patterned mask, and performing a liquid etching process on the copper layer through the patterned mask to from an array of bottom connection pads 142 on partial surface of the carrier 220. In other embodiment, the bottom connection pads 142 may be formed through a semi-additive process in replace of the above-mentioned copper etching process, and not limited thereto.

Furthermore, as shown in FIG. 8, molding and grinding processes are performed to form the lower basic dielectric layer 13a. For example, the molding process includes providing a dielectric material on the bottom connection pads 142 and the carrier 220, and performing a lamination process on the dielectric material to form the basic dielectric layer 13a on the carrier 220 and the bottom connection pads 142. The grinding process may include performing a chemical mechanical polishing (CMP) process or mechanical grinding process to thin the basic dielectric layer 13a and to expose the bottom connection pads 142. The bottom surface of the basic dielectric layer 13a is the basic bottom surface 131.

Next, as shown in FIG. 9, the redistribution layer 35 of the upper basic connection layer 14b is formed on the bottom connection pads 142 and the basic dielectric layer 13a through a semi-additive process, and numbers of via plugs 37 are formed on the redistribution layer 35 through a copper plug plating process. Thereafter, as shown in FIG. 10, molding and grinding processes are performed to form the upper basic dielectric layer 13b on the basic connection layer 14b, and to expose the via plugs 37. Next, as shown in FIG. 11, a redistribution layer 35 of the lower support connection layers 54a is formed through a semi-additive process.

According to the above-mentioned steps, the basic connection layers 14a, 14b and the basic dielectric layers 13a, 13b are formed on the carrier 220. The basic connection layers 14a, 14b are located in the basic dielectric layers 13a, 13b individually. A chip-placing area 30 is defined on a portion of the basic top surface 132 of the basic dielectric layers 13a, 13b.

Next, as shown in FIG. 12, a release film 42 is adhered onto the surface of the chip-placing area 30. Thereafter, as shown in FIG. 13, a molding process is performed to form the lower support dielectric layers 53a, and a laser drilling process is performed on the support dielectric layers 53a to form numbers of via holes 38 in the support dielectric layers 53a. Furthermore, as shown in FIG. 14, numbers of via plugs 37 is formed by filling the via holes 38 with conductive material through an electroless copper plating process, an electrolytic copper plating process or a deposition process. Thereafter, the upper support connection layer 54b is formed on the lower support dielectric layer 53a through a semi-additive process. The upper support connection layer 54b includes a redistribution layer 35 and a layer of via plugs 37, which are electrically connected to the support connection layers 54a. Next, as shown in FIG. 15, a molding process is performed to form the upper support dielectric layer 53b, and a grinding process is performed to expose the second connection pads 542. Some of the second connection pads 542 on the substrate 10 may be applied for wire bonding connection, since the via plugs 37 are proper support for wire bonding connection.

According to the above-mentioned steps, the support dielectric layers 53a, 53b and the support connection layers 54a, 54b are formed on the basic dielectric layers 13a, 13b. The support dielectric layers 53a, 53b are located on the basic top surface 132 of the basic dielectric layers 13a, 13b. The support connection layers 54a, 54b are located in the support dielectric layers 53a, 53b individually. The second connection pads 542 of the support connection layers 54b are exposed on support top surface 532 of the support dielectric layers 53a, 53b.

Afterward, as shown in FIG. 16, a protective film 44 is provided to cover the surfaces of the support connection layers 54b and the support top surface 532 of the support dielectric layers 53b. Thereafter, a laser dicing process is performed on the chip-placing area 30. The protective film 44 protects the second connection pads 542 and the support dielectric layers 53b during the dicing process. Next, a portion of the protective film 44 on the chip-placing area 30 is picked up by a vacuum sucker. Since the release film 42 is located on the chip-placing area 30, materials above the chip-placing area 30 (including the release film 42, the support dielectric layers 53a, 53b and the protective film 44) can all be picked up together to expose the chip-placing area 30. Thus, the support dielectric layers 53a, 53b and the basic dielectric layers 13a, 13b together shape the chip-placing recess 31.

In the embodiment, since the binding force between the support dielectric layer 53a with the release film 42 is greater than the binding force between the redistribution layer 35 corresponding to the chip-placing area 30 with the release film 42 so that the release film 42 is separated from the redistribution layer 35 corresponding to the chip-placing area 30 by internal stress when performing the laser dicing process.

In other embodiments, the release film may be disposed on the basic dielectric layer, in such a case, the binding force between the support dielectric layer with the release film is greater than the binding force between the basic dielectric layer with the release film so that the release film is separated from the basic dielectric layer corresponding to the chip-placing area by internal stress when performing the laser dicing process.

Moreover, as shown in FIG. 17, an etching process is performed on the basic connection layers 14a, 14b in the chip-placing area 30 to expose the first connection pads 141.

Next, as shown in FIG. 18, the carrier 220 and the protective film 44 are removed from the basic bottom surface 131 of the basic dielectric layer 13a. Portions of the basic connection layer 14b exposed on the basic top surface 132 of the basic dielectric layer 13b are applied as numbers of first connection pads 141. Portions of the basic connection layer 14a exposed on the basic bottom surface 131 of the basic dielectric layer 13a are applied as numbers of bottom connection pads 142. Thus, the substrate 10 of the first embodiment (the semiconductor package structure 100) is manufactured.

Thereafter, a die bond process and a molding process can be further performed to form the semiconductor package structure 200, 300 of the above-mentioned second and third embodiments. For example, a flip-chip process is performed to connect the first chip 21. Numbers of first bumps 46 is formed on the electric pads of the first chip 21. The first bumps 46 are electrically conductive elements, such as the solder balls. Next, the first chip 21 is disposed in the chip-placing recess 31 with the first active surface 211 downward to the basic dielectric layer 13b. The first bumps 46 electrically connecting to the electric pads in the first active surface 211 of the first chip 21 and the first connection pads 141 of the substrate 10. Afterward, a flip-chip process and a wire bond process are performed to connect to the second chip 22 and the third chip 23 individually. A lamination process is than performed to form the encapsulation layer 64 on the substrate 10 to cover the first bumps 46, the whole first chip 21 and the whole support top surface 532 of the substrate 10. Thereafter, numbers of third bumps 48 are selectively formed on the basic bottom surface 131 of the substrate 10. The third bumps 48 are applied as outer connection pads to connect each of the semiconductor package structures 100, 200, 300 to printed circuit boards 50 individually.

The thickness of each of the support connection layers 54a, 54b and the thickness of each of the support dielectric layers 53a, 53b are less than the chip thickness of the embedded first chip 21 in the above-mentioned embodiments. The support connection layers 54a, 54b are easily formed in the support dielectric layers 53a, 53b through the semi-additive processes in the present invention. The wafer-level copper processes are no longer needed to form the traditional huge copper plugs around the lower chip for supporting the upper chip. In addition to the hardness of the wafer-level copper processes, another disadvantage of the traditional huge copper plugs is that the huge copper plugs can only conduct upwardly in one direction. On the contrary, the support connection layers 54a, 54b of the present invention can redistribute the traces, so a projection of the support connection layers 54a, 54b projected on the support top surface 532 is different from a projection of the second connection pads 542 projected on the support top surface 532. In other words, there are horizontal support connection layers 54a, 54b between adjacent second connection pads 542 in the top view.

Two support dielectric layers 53a, 53b are formed as an example to describe various inventive embodiments, but the number of the support dielectric layers is not limited thereto. In other embodiment, more than three support connection layers 54a, 54b may be formed between an extension surface of the first back surface 212 and an extension surface of the first active surface 211 of the first chip 21, and the thickness of each support dielectric layer 53a, 53b is less than the chip thickness of the first chip 21. Since the layers of the substrate 10 are formed layer by layer through the directly build-up technology, the present invention can reduce the interlayer offset and forms any number of layers easily. In addition, the structure and the method of the present invention ay by applied to a single chip molding package. In other words, the semiconductor package structure 200 may omit the second chip 22 and the second bumps 47.

In summary, the present invention relates to a substrate, which utilizes the build-up interconnection technology and rear recess laser forming technology to form first connection pads on the recess bottom for a flip chip package. The lower chip is partially or wholly embedded in the recess, and is electrically connected to the first connection pads on the recess bottom. One or more chips may be stacked on the lower chip. In addition, since the single substrate of the present invention can provide both support and interconnection for numbers of chip, no more huge copper plugs or giant solder balls are needed. Thus, the present invention provides a thinner system package, improves the heat dissipation and increases the structural reliability.

Even though numerous characteristics and advantages of certain inventive embodiments have been set out in the foregoing description, together with details of the structures and functions of the embodiments, the disclosure is illustrative only. Changes may be made in detail, especially in matters of arrangement of parts, within the principles of the present disclosure to the full extent indicated by the broad general meaning of the terms in which the appended claims are expressed.

What is claimed is:

1. A semiconductor package structure, comprising:
a first chip, the first chip having a first active surface and a first back surface opposite to the first active surface; and
a substrate, the substrate comprising:
at least one basic dielectric layer, the basic dielectric layer having a basic top surface and a basic bottom surface opposite to the basic top surface;
at least one basic connection layer disposed in the basic dielectric layer, the basic connection layer comprising a plurality of first connection pads exposed on the basic top surface and a plurality of bottom connection pads exposed on the basic bottom surface;
a plurality of support dielectric layers, the support dielectric layers and the first chip disposed on the basic top surface of the basic dielectric layer, the support dielectric layers and the basic dielectric layer together shaping a chip-placing recess, the first chip being disposed in the chip-placing recess with the first active surface downward to the basic dielectric layer, the first active surface of the first chip being electrically connected to the first connection pads; and
a plurality of support connection layers disposed in the support dielectric layers, the support connection layers comprising a plurality of second connection pads exposed on the support top surface.

2. The semiconductor package structure of claim 1, further comprising a second chip, the second chip having a second active surface, wherein the second chip is disposed above the first chip and the support top surface of the support dielectric layers, and the second chip is electrically connected to the second connection pads through the second active surface downwardly.

3. The semiconductor package structure of claim 2, further comprising:
a plurality of first bumps, the first bumps electrically connecting the first chip and the first connection pads; and
a plurality of second bumps, the second bumps electrically connecting the second chip and the second connection pads.

4. The semiconductor package structure of claim 2, further comprising a third chip, the third chip having a third active surface, wherein the third chip is disposed on the second chip with the third active surface upwardly, and the third chip is electrically connected to the second connection pads through a plurality of wires.

5. The semiconductor package structure of claim 1, wherein a thickness of each of the support dielectric layers is less than a chip thickness of the first chip.

6. The semiconductor package structure of claim 1, wherein each of the support connection layers comprises a redistribution layer and a plurality of via plugs electrically connected to the redistribution layer.

7. The semiconductor package structure of claim 1, wherein the first back surface of the first chip is substantially even with the support top surface of the support connection layers.

8. The semiconductor package structure of claim 1, wherein a projection of the support connection layers projected on the support top surface is different from a projection of the second connection pads projected on the support top surface.

9. The semiconductor package structure of claim 1, wherein the basic dielectric layer and the support dielectric layers are high filler content dielectric materials, which mainly comprises epoxy.

10. A method of making a semiconductor package structure, comprising:
providing a carrier;
forming at least one basic connection layer and at least one basic dielectric layer on the carrier, the basic connection layer being disposed in the basic dielectric layer, a basic top surface of the basic dielectric layer having a chip-placing area;
providing a release film on the chip-placing area;
forming a plurality of support dielectric layers and a plurality of support connection layers on the basic dielectric layer, the support dielectric layers being disposed on the basic top surface of the basic dielectric layer, the support connection layers being disposed in the support dielectric layers, the support connection layers comprising a plurality of second connection pads exposed on the support top surface of the support dielectric layers;
performing a dicing process on the chip-placing area to remove parts of the support dielectric layers and parts of the release film located on the chip-placing area and to expose the chip-placing area, the support dielectric layers and the basic dielectric layer together shaping a chip-placing recess; and
removing the carrier, the basic connection layer comprising a plurality of first connection pads exposed on the basic top surface of the basic dielectric layer, the basic connection layer comprising a plurality of bottom connection pads exposed on a basic bottom surface of the basic dielectric layer.

11. The method of claim 10, further comprising:
providing a protective film covering the support top surface of the support dielectric layers, before the dicing process is performed, the protective film protecting the second connection pads during the dicing process;
performing an etching process on the basic connection layer in the chip-placing area to expose the first connection pads; and
removing the protective film.

12. The method of claim 10, wherein the release film is separated from the chip-placing area by internal stress when performing the dicing process.

13. The method of claim 12, wherein the binding force between the support dielectric layer with the release film is greater than the binding force between the chip-placing area with the release film.
